(19) United States
(12) Patent Application Publication
(10) Pub. No.: US 2009/0251127 A1
(43) Pub. Date: Oct. 8, 2009

(54) Power Management Connection Devices And Related Methods

(75) Inventor: John Kim, Los Angeles, CA (US)

Correspondence Address: BRYAN CAVE LLP, TWO NORTH CENTRAL AVENUE, SUITE 2200, PHOENIX, AZ, 85004, US

(73) Assignee: Belkin International, Inc., Compton, CA (US)

(21) Appl. No.: 12/417,946

(22) Filed: Apr. 3, 2009

Related U.S. Application Data
(60) Provisional application No. 61/042,175, filed on Apr. 3, 2008.

(51) Int. Cl. G01R 19/00

(52) U.S. Cl. 324/76.11

(57) ABSTRACT

Embodiments of power management connection devices and related methods are described herein. Other embodiments and related methods are also disclosed herein

### CROSS REFERENCE TO RELATED APPLICATION

This application claims priority to U.S. Provisional Patent Application 61/402,175, filed on Apr. 3, 2008, the contents of which are incorporated herein by reference.

### FIELD OF THE INVENTION

This invention relates generally to electrical connection devices, and relates more particularly to power management connection devices.

### BACKGROUND

The present trend toward energy conservation has spawned new needs for more flexible and efficient means for monitoring and controlling power consumption. At least at the residential level, options exist for devices that can help to monitor power consumption of specific power outlets, such as the Kill A Watt™ monitor from P3 International Corporation, of New York, N.Y. Nevertheless, current methods for monitoring power consumption are still not flexible enough, requiring users to be at the same location as the monitored power outlet in order to control it, and failing to provide adequate provisions for remote monitoring and control of specific power outlets. Accordingly, a needs exist for devices and methods that address such limitations of the current technology.

### BRIEF DESCRIPTION OF THE DRAWINGS

The invention will be better understood from a reading of the following detailed description of examples of embodiments, taken in conjunction with the accompanying figures in the drawings in which:

FIG. 1 illustrates an isometric internal view of a connection device of a power management system;

FIG. 2 illustrates an isometric internal view of a different embodiment of a connection device of the power management system;

FIG. 3 illustrates a diagram of the power management system, showing the electrical connector of FIG. 1 coupled to a power network;

FIG. 4 illustrates a flowchart of a method for manufacturing a connection device similar to the connection device of FIGS. 1-2; and

FIG. 5 illustrates a flowchart of a method for using a connection device similar to the connection device of FIGS. 1-2.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Furthermore, the terms “include,” and “have,” and any variations thereof, are intended to cover a non-exclusive inclusion, such that a process, method, system, article, device, or apparatus that comprises a list of elements is not necessarily limited to those elements, but may include other elements not expressly listed or inherent to such process, method, system, article, device, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein.

The terms “couple,” “coupled,” “couples,” “coupling,” and the like should be broadly understood and refer to connecting two or more elements or signals, electrically, mechanically and/or otherwise. Two or more electrical elements may be electrically coupled together but not be mechanically or otherwise coupled together; two or more mechanical elements may be mechanically coupled together, but not be electrically or otherwise coupled together; two or more electrical elements may be mechanically coupled together, but not be electrically or otherwise coupled together. Coupling may be for any length of time, e.g., permanent or semi-permanent or only for an instant.

An electrical “coupling” and the like should be broadly understood and include coupling involving any electrical signal, whether a power signal, a data signal, and/or other types or combinations of electrical signals. A mechanical “coupling” and the like should be broadly understood and include mechanical coupling of all types. The absence of the word “removably,” “removable,” and the like near the word “coupled,” and the like does not mean that the coupling, etc. in question is or is not removable.

### DETAILED DESCRIPTION

In one embodiment, a power management system comprises a connection device. The connection device comprises an electrical outlet, a power consumption meter coupled to the electrical outlet, a network interface coupled to the power consumption meter, and a power adapter coupled to the network interface. The power consumption meter is configured to measure a power consumption of the electrical outlet. In addition, the network interface is configured to transmit information about the power consumption via the power adapter. Other embodiments of power management systems and connection devices are disclosed below.

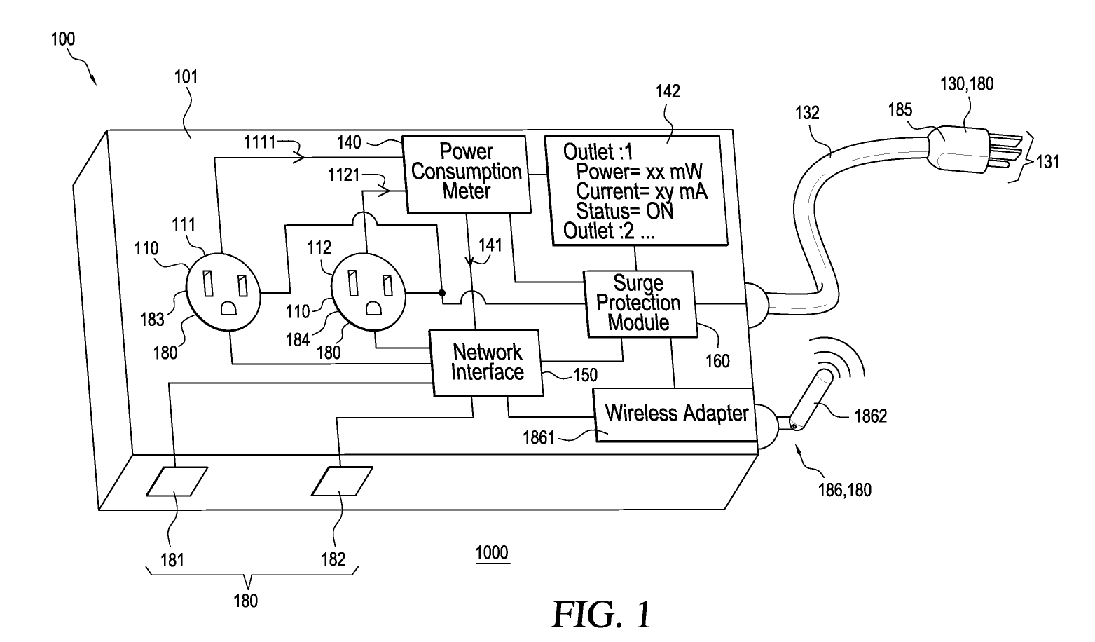

Turning to the drawings, FIG. 1 illustrates an isometric internal view of connection device 100 of power management system 1000.

Connection device 100 comprises electrical outlet set 110 comprising electrical outlet 111. In the present example, electrical outlet electrical outlet 111 is a standard U.S. grounded electrical socket with a line slot, a neutral slot, and a ground slot. Electrical outlet 111 can couple an electrical device (not shown) to connection device 100 by accommodating power prongs from a power plug of the electrical device. As will be described below, when coupled as such, connection device 100 can power the electrical device by providing a power path through electrical outlet 111 to the power plug of the electrical device. In a different example, electrical outlet 111 can instead comprise an ungrounded electrical socket, thus foregoing the ground slot and the capability of directly accommodating grounded power plugs from other electrical devices. In another example, electrical outlet 111 can be compliant with electrical outlet standards of countries other than the United States.

In the present example, electrical outlet set 110 also comprises electrical outlet 112, which is similar to electrical outlet 111. In a different example, electrical outlet 112 can differ from electrical outlet 111 by being ungrounded, or by complying with an electrical outlet standard from another country. In another example, connection device 100 can comprise additional electrical outlets similar to or different from electrical outlets 111-112, or may comprise instead only one of electrical outlets 111 or 112.

Connection device 100 also comprises power adapter 130. Power adapter 130 can comprise a power plug with power prongs 131 configured to couple with an external power source (not shown). In the present example, as will be further described below, power adapter 130 is coupled to electrical outlet set 110 internally through connection device 100. Also in the present example, power adapter 130 comprises a power cord 132 to couple with body 101 of connection device 100. In different embodiment, however, power adapter 130 can forego power cord 132 and couple directly to body 101. When power prongs 131 of power adapter 130 are coupled to the external power source (not shown), power can be routed internally through connection device 100 to electrical outlet set 110. In another embodiment, power adapter 130 can be compliant with an electrical standard of a different country and/or can be a cigarette lighter adapter.

In the present example, connection device 100 comprises surge protection module 160. Surge protection module 160 is coupled between power adapter 130 and electrical outlet set 110 of connection device 100. Surge protection module 160 is configured to protect electrical devices coupled to electrical outlet set 110 from voltage spikes, current spikes, or other power conditioning inconsistencies of the external power source by, for example, blocking or shorting to ground voltages above a safe threshold. In a different example, surge protection module 160 is not provided, and the electrical path between electrical outlet set 110 and power adapter 130 would be more direct while foregoing protection against power, current, and/or voltage conditioning inconsistencies.

Connection device 100 further comprises power consumption meter 140 coupled to electrical outlet 111 within housing 101. In the present example, power consumption meter 140 is also coupled to electrical outlet 112. In a different embodiment, power consumption meter 140 can be further coupled to other electrical outlets of electrical outlet set 110 besides electrical outlets 111-112. In another embodiment, a separate power consumption meter can be coupled to electrical outlet 112 while power consumption meter 140 is coupled to electrical outlet 111. In a further embodiment, only one of electrical outlet 111 or 112 is coupled to a power consumption meter.

Power consumption meter 140 comprises circuitry configured to measure a power consumption 1111 of electrical outlet 111. When coupled to electrical outlet 111, an electrical device can draw current and/or consume power sourced through electrical outlet 111 of connection device 100. Under such circumstances, because power consumption meter 140 is coupled to electrical outlet 111, power consumption meter 140 can measure power consumption 1111 drawn by the electrical device.

In one embodiment, power consumption 1111 measured by power consumption meter 140 can comprise power factors such as a current drain, a voltage level, and/or a power status of the electrical device. In turn, the power status can comprise data indicating whether the electrical device is in an “on” or powered status, an “off” status, a hibernate or standby status, and/or the date and/or time that a change in such status occurred, among others. In other embodiments, power consumption meter 140 may measure one or more of the power factors, and then determine other power factors based on the measured ones. Some or all of this information can be compiled for all devices coupled to device 100 and/or can be maintained individually for each electrical outlet in electrical outlet set 110 or for only certain ones of the electrical outlets. Device 100 can display some or all of this information via display 142. In the present embodiment, because power consumption meter 140 is also coupled to electrical outlet 112, power consumption meter 140 can also measure power consumption 1121 of electrical outlet 112. In another embodiment, power consumption meter 140 can be coupled to power adapter 130 to directly measure the aggregate power factors of device 100. In another embodiment, power consumption meter 140 measures only the power factors from electrical outlet set 110 and not any power factors resulting from other portions of network device 100 such as, for example, display 142, network interface 150, or wireless adapter 1861.

Connection device 100 also comprises network interface 150 coupled to power consumption meter 140. In the present example, network interface 150 is also coupled to power adapter 130 via surge protection module 160. In a different example, network interface 150 can be coupled directly to power adapter 130. Network interface 150 is configured to transmit power consumption information 141 about power consumption 1111 via power adapter 130. Network interface 150 receives power consumption information 141 from power consumption meter 140.

In the present example, power consumption information 141 also comprises information about power consumption 1121. In a different embodiment, power consumption information 141 comprises only information about power consumption 1111, while information regarding other, if any, electrical outlets of electrical outlet set 110 can reach network interface 150 via other power consumption meters (not shown). In a different embodiment, information about other electrical outlets of electrical outlet set 110 can be sent to a different network interface via other or the same power consumption meters.

Network interface 150 can process and/or encode power consumption information 141 through a suitable format for transmission via power adapter 130. As an example, network interface 150 can encode data, such as power consumption information 141, using one of a frequency shift keying (FSK) mechanism, or an orthogonal frequency-division multiplexing (OFDM) mechanism. In the same or a different example, network interface 150 can transmit the data over power adapter 130, compliant with a power network communication standard such as a HomePlug Alliance standard, a Consumer Electronics Powerline Communications Alliance (CEPCA) standard, and a Universal Powerline Association (UPA) standard. Once network interface 150 processes power consumption information 141 as described above, network interface 150 can transmit power consumption information 141 via power adapter 130.

In the present example, electrical connector 100 also comprises a communications port set 180 coupled to network interface 150. Communications port set 180 can comprise one or more ports, such as ports 181-186, located at an exterior of connection device 100. The one or more ports of communications port 180 are capable of coupling electrical devices (not shown) to connection device 100, and can constitute a communications path via network interface 150 between the coupled electrical devices.

In one example, the one or more ports of communications port set 180, such as ports 181-182, can comprise an Ethernet port, a USB port, and/or an optical interface port, among others. In the same or a different example, communications port set 180 can comprise a wireless port, such as port 186. As illustrated in FIG. 1, port 186 can comprise a wireless adapter 1861 coupled to network interface 150, and an antenna 1862 coupled to wireless adapter 1861, where antenna 1862 can be external or internal to body 101.

In same or another embodiment, the one or more ports of communications port set 180 can correspond to one or more of the electrical outlets of electrical outlet set 110. For example, port 181 can correspond to electrical outlet 111 by transmitting information to, from, and/or regarding an electrical device coupled to electrical outlet 111 and/or electrical outlet 112. In the same or another embodiment, port 182 can similarly correspond to electrical outlet 112.

In the same or a different example, the one or more electrical outlets of electrical outlet set 110 can themselves comprise one or more ports of communications port set 180. For example, electrical outlet 111 can comprise port 183 while electrical outlet 112 can comprise port 184. In the same or a different example, electrical adapter 130 can also comprise one of the ports of communications port set 180, such as port 185 in the present example. In this example, the electrical wiring of the house or building providing the power to device 100 can also serve as the network wiring through which the power factors and/or other related information are transmitted.

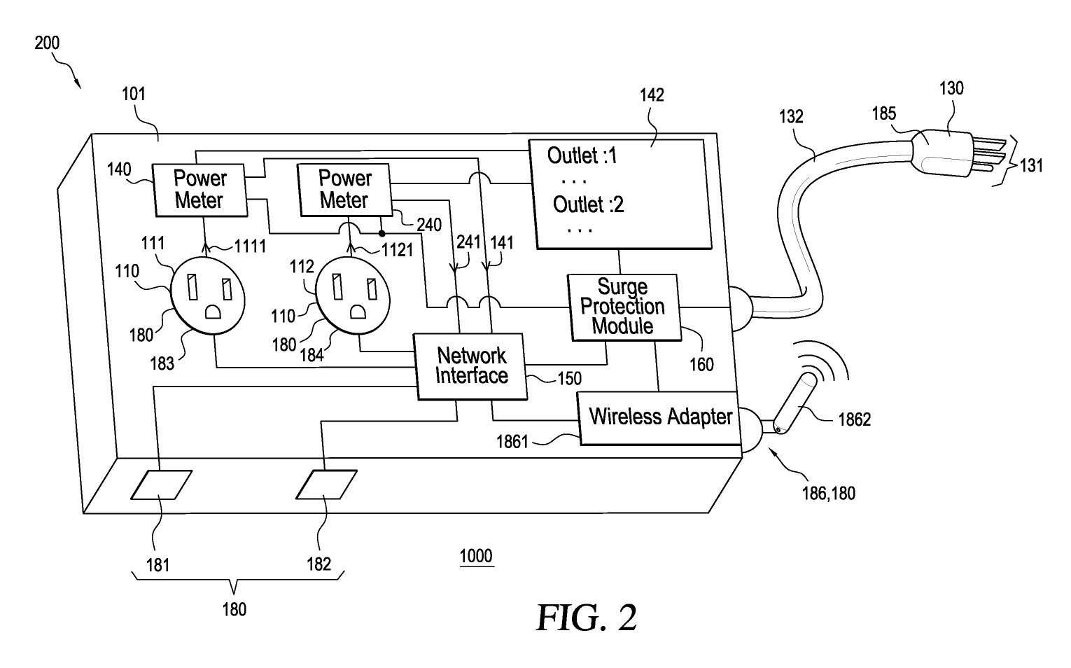

Continuing with the figures, FIG. 2 illustrates an internal view of connection device 200. Connection device 200 is a similar embodiment to connection device 100 from FIG. 1, and is also capable of forming part of power management system 1000. However, connection device 200 differs from connection device 100 by comprising power consumption meter 240 coupled to network interface 150.

For connection device 200, in contrast to connection device 100 of FIG. 1, electrical outlet 112 couples to power consumption meter 240. As a result, for connection device 200, power consumption 1121 of electrical outlet 112 is measured by power consumption meter 240 rather than by power consumption meter 140. Power consumption meter 240 can then make power consumption information 241 about power consumption 1121 available to network interface 150. Having access to power consumption information 241, network interface 150 can then transmit power consumption information 241 via power adapter 130, similar to as described in FIG. 1 for power consumption information 141 of electrical connector 100.

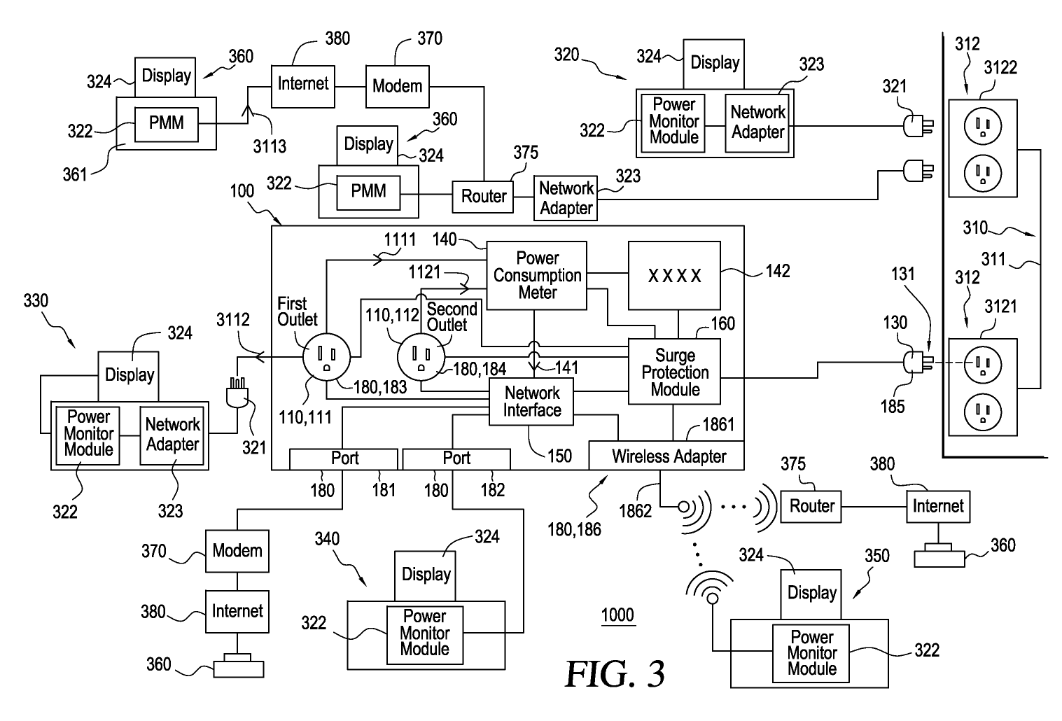

Continuing with the figures, FIG. 3 illustrates a diagram of power management system 1000, showing connection device 100 coupled to power network 310.

Power network 310 comprises electrical wiring 311 and is capable of supplying power to power outlet set 312. In the present embodiment, power outlet set 312 comprises two power outlets 3121 and 3122, coupled together via electrical wiring 311. In a different embodiment, power network 310 can comprise other power outlets coupled together via electrical wiring 311. The power outlets of power outlet set 312 can comprise alternating-current (AC) wall outlets, as illustrated in FIG. 3 for power outlets 3121 and 3122. Power network 310 can be compliant with an AC standard of 110-120 volts at a frequency of 60 Hz. In a different embodiment, power network 310 can support a different AC standard of 220-240 volts at 50 Hz. Other direct-current (DC) or AC standards are similarly possible for power network 310.

As illustrated for power management system 1000 in FIG. 3, connection device 100 can be coupled to power network 310 by inserting power prongs 131 of power adapter 130 into one of the power outlets of power outlet set 312, such as power outlet 3121. When coupled as such, network interface 150 can transmit power consumption information 141, as described for FIG. 1, through power network 310 via power adapter 130.

Power management system 1000 can comprise electrical device 320 coupled to power network 310 through power outlet set 312. In the present example, electrical device 320 comprises power plug 321 to couple to power outlet 3122, where power plug 321 can be a standard power plug with prongs complementary to power outlet 3122, similar to as described in FIG. 1 for power adapter 130 of connection device 100.

Electrical device 320 comprises power monitoring module 322 and display 324 coupled to power monitoring module 322. Power monitoring module 322 can comprise a processor capable of executing software instructions to communicate with other electrical devices. Power monitoring module 322 is also capable of controlling display 324. In the present example, power monitoring module 322 couples to network interface 150 of connection device 100 through power network 310, via a path comprising network adapter 323, power outlet 3122, electrical wiring 311, power outlet 3121, power adapter 130, surge protection module 160, and finally network interface 150. As will be described further below, other alternative paths are possible for other power monitoring modules 322 in other electrical devices 330, 340, 350, and 360 to couple and/or communicate with network interface 150.

In the example of FIG. 3, network adapter 323 is configured to decode information received through power network 310 to a format compatible with power monitoring module 322. In the same or a different embodiment, network adapter 323 can encode information from power monitor module 322 to a format compatible for transmission through power network 310. In the same or a different example, the information can be encoded or decoded using an FSK or an OFDM mechanism, and/or using one of the power network communication standards described for FIG. 1 for network interface 150. In a different embodiment, network adapter 323 can form part of and/or be integrated with power monitoring module 322.

When power monitor module 322 couples to network interface 150, whether through the path described above or through an alternative path, power monitor module 322 can communicate with and receive data from network interface 150, such as power consumption information 141. Power monitor module 322 can then control display 324 to present power consumption information 141 in a desired and/or predetermined format.

In the same or a different example, a power monitor module 322 can couple with network interface 150 via different paths comprising at least one of an electrical outlet from electrical outlet set 110, a power adapter such as power adapter 130, a network adapter such as network adapter 323, a power network such as power network 310, a modem such as one of modems 370, a router such as one of routers 375, Internet 380, and/or one or more of the ports of communications port set 180. The ports of communications port set 180, such as ports 181-186, can comprise an Ethernet connection, an optical interface, a wireless connection, and/or an USB connection, among others. In the same or a different example, the power network can be referred to as a power grid or a powerline network; the power adapter can be referred to as a power plug; and/or the network adapter can be referred to as a powerline adapter.

As illustrated in FIG. 3, power monitor module 322 can form part of other electrical devices, such as electrical devices 330, 340, 350, and 360, that communicate with network interface 150 through alternative paths as described above. For example, electrical device 330 couples to network interface 150 via electrical port 183, comprising electrical outlet 111. Similar to electrical device 320, electrical device 330 can comprise a network adapter 323 to encode and/or decode data communicated to and/or from network interface 150, such as power consumption information 141.

Similarly, power monitoring module 322 of electrical device 340 can couple to network interface 150 through one or more of ports 181-182 of communications port set 180, comprising an Ethernet connection, an optical interface connection, and/or a USB connection, among others. In this example, because communications with network interface 150 would not involve a path through a power network such as power network 310, electrical device 340 may forego the use of a network adapter.

In the present example, power monitoring module 322 of electrical device 350 couples to network interface 150 through port 186 of communications port set 180, comprising a wireless connection. As illustrated in FIG. 3, port 186 couples with network interface 150 and comprises wireless adapter 1861 with antenna 1862. For the same reasons as for electrical device 340, electrical device 350 can also forego the use of a network adapter.

Power management system 1000 can also comprise power monitoring modules 322 of different electrical devices 360, where electrical devices 360 couple to network interface 150 via communication devices such as modems 370, routers 375, and/or Internet 380. Different examples of such possible alternative paths are illustrated in FIG. 3 for different electrical devices 360.

Regardless of the path taken to couple with network interface 150, the power monitor module 322 of one or more of electrical devices 320-360 is configured to process power consumption information of electrical outlet set 110, such as power consumption information 141. Once processed, power monitor module 322 can cause a display, such as display 324, to display the power consumption information. In one example, power monitor module 322 can process power consumption information 141 to display at least one of a current drain, a power status, and/or a voltage level of one or more of the electrical outlets of electrical outlet set 110. In the same or a different example, the power status can comprise information about whether an electrical device coupled to one of the electrical outlets is on, off, in standby mode, or in hibernate mode, among others. In the same or a different example, the power consumption information is presented on the display via a graphical user interface (GUI).

In the same or a different embodiment, power monitor module 322 is configured to control a power output of one or more of the electrical outlets of electrical outlet set 110 via network interface 150. As an example, as shown in FIG. 3, a power monitor module 322 of one of electrical devices 320, 330, 340, 350, and 360 coupled to network interface 150 can control power output 3112 from electrical outlet 111 to electrical device 330. In the present embodiment, network interface 150 controls a magnitude of power output 3112 via power consumption meter 140. In the same or a different example, network interface 150 can control a different power output from a different electrical outlet of electrical outlet set 110 via a different power consumption meter associated with the different electrical outlet. One such example can comprise power monitor module 240 and electrical outlet 112, as shown in FIG. 2.

In one example, power monitor module 322 is configured to accept a control input to control the power output 3112 of electrical outlet 111 at connection device 100. Other power outputs from different electrical outlets can be similarly controlled. In one embodiment, the control input can be entered via the GUI presented on display 324.

As an example of how power monitor 322 can control power output of electrical outlet set 110, as illustrated in FIG. 3, electrical device 330 is coupled to electrical outlet 111 of connection device 100 and draws power consumption 1111, sourced through power output 3112 from electrical outlet 111. Power consumption 1111 is then processed by power consumption meter 140 to generate power consumption information 141. Network interface 150 gathers power consumption information 141 and transmits it via communications port set 180, including port 185 comprising power adapter 130. For transmissions via power adapter 130, network interface 150 can encode power consumption information 141 prior to transmittal through power network 310. Power consumption information 141 is eventually received by power monitor module 322 of one of electrical devices 360 after propagating through other elements of power management system 1000 as illustrated in FIG. 3.

When power monitor module 322 receives, processes, and displays on its respective display 324 communications from network interface 150, such as power consumption information 141, a user can react to the displayed information and enter control input 3113 for transmittal to network interface 150. For instance, the user may think electrical device 330 is drawing too much power output 3112, or may realize that he forgot to turn either off or on electrical device 330. In such cases, the control input 3113 can be entered to control power output 3112 of electrical outlet 111. In a different example, power monitor module 322 is configured to automatically emit control input 3113 to control power output 3112 of electrical outlet 111 based on power consumption information 141, such as when power consumption information 141 reaches a certain threshold, or when a predetermined time or schedule is reached. Once entered, the control input 3113 propagates through power management system 1000, in an opposite direction to what was described above for power consumption information 141, until reaching network interface 150. Network interface 150 then processes control input 3113 and, for the present example, controls the magnitude of power output 3112 through power consumption meter 140.

In the same or a different embodiment, connection device 100 can serve to allow communications between different networking devices coupled to communications port set 180. For example, the networking devices can be as described above, including electrical devices 320, 330, 340, 350, and 360, modems 370, and routers 375. In one embodiment, a networking device can couple to a port of communications port set 180, while a different networking device can couple to a different port of communications port set 180. When coupled as such, both networking devices have access to network interface 150, and can communicate with each other using network interface 150 as an intermediary.

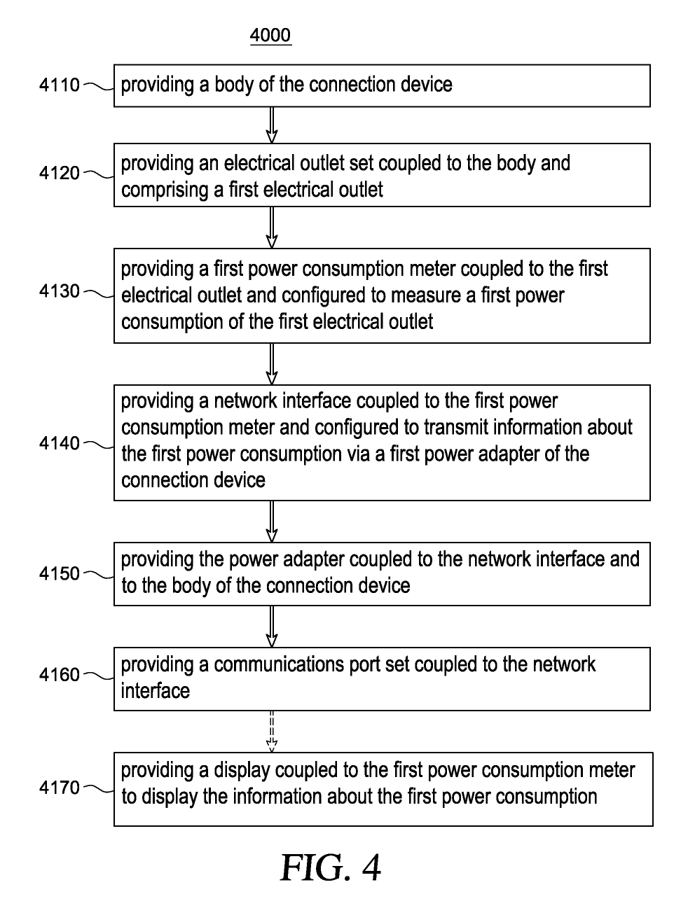

Continuing with the figures, FIG. 4 illustrates a flowchart of a method 4000 for manufacturing a connection device in accordance with the present disclosure. In some examples, the connection device of method 4000 can be similar to connection device 100 (FIGS. 1, 3) or to connection device 200 (FIG. 2).

Block 4110 of method 4000 comprises providing a body of the connection device of method 4000. In some examples the body of the connection device can be similar to body 101 of connection device 100 (FIGS. 1, 3) or to a body of connection device 200 (FIG. 2).

Block 4120 of method 4000 comprises providing an electrical outlet set coupled to the body of block 4110 and comprising a first electrical outlet. In some examples, the electrical outlet set can be similar to electrical outlet set 110 (FIGS. 1-3), and the first electrical outlet can be similar to electrical outlet 111 (FIGS. 1-3).

Block 4130 of method 4000 comprises providing a first power consumption meter coupled to the first electrical outlet of block 4120 and configured to measure a first power consumption of the first electrical outlet. The first power consumption meter can be similar to one of power consumption meters 140 (FIGS. 1, 3) or 240 (FIG. 2) in some examples. In the same or a different example, the power consumption of block 4130 can be similar to power consumption 1111 as described above for electrical outlet 111.

Block 4140 of method 4000 comprises providing a network interface coupled to the first power consumption meter of block 4130 and configured to transmit information about the first power consumption via a first power adapter. As an example, referring to the embodiments of FIGS. 1-3, the network interface of block 4140 can be similar to network interface 150, while the first power adapter can be similar to power adapter 130. In the same or a different example, the information about the first power consumption can be similar to one of information 141 (FIGS. 1-3) or 241 (FIG. 2). The network interface can also be used in some examples to control, via the first power consumption meter of block 4130, a first power output of the first electrical outlet. For example, the first power output of the first electrical outlet can be similar to power output 3112 (FIG. 3).

Block 4150 of method 4000 comprises providing the power adapter coupled to the network interface and to the body of the connection device. In some examples, the power adapter can couple to the body through a cord, as shown for power adapter 130 coupled to body 101 through power cord 132 (FIGS. 1-2). In the same or a different example, the power adapter can also couple to the network interface of block 4140 internally through the body of the connection device, as shown in FIGS. 1-3 for the coupling between power adapter 130 and network interface 150.

Block 4160 of method 4000 comprises providing a communications port set coupled to the network interface. In some embodiments, the communications port set can be similar to communications port set 180 (FIGS. 1-3), and/or can comprise at least one of the electrical outlet set of block 4120, the power adapter of block 4150, an Ethernet port, a USB port, an optical interface port, or a wireless port.

Block 4170 of method 4000 comprises providing a display coupled to the first power consumption meter to display the information about the first power consumption. In some examples, the display of block 4170 can be similar to display 142 (FIGS. 1-3).

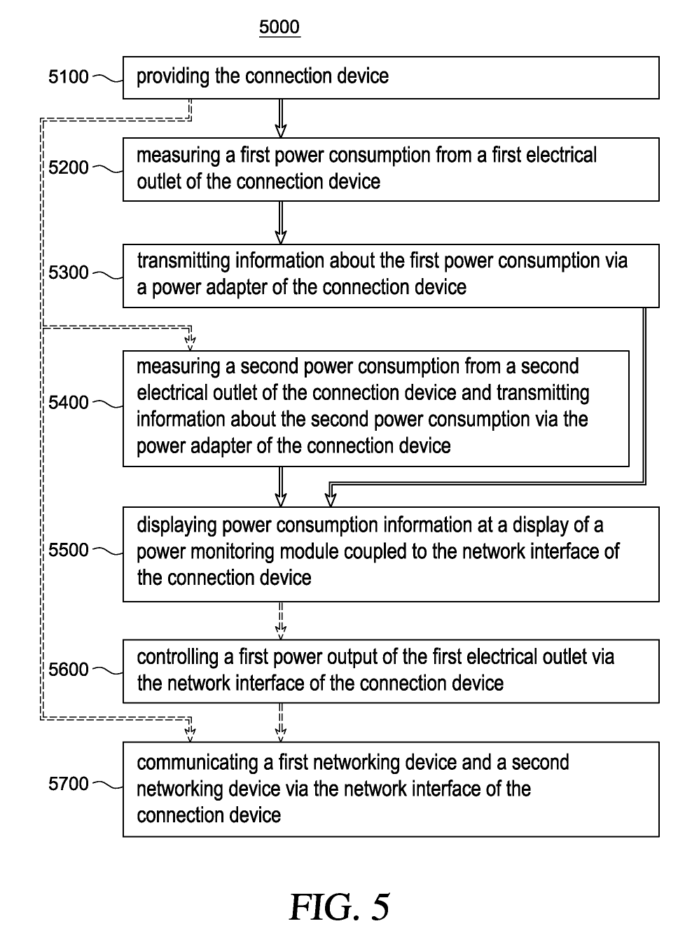

Moving along, FIG. 5 illustrates a flowchart of a method 5000 for using a connection device in accordance with the present disclosure. In some examples, the connection device of method 4000 can be similar to connection device 100 (FIGS. 1, 3), to connection device 200 (FIG. 2), or to the connection device of method 4000 (FIG. 4).

Block 5100 of method 5000 comprises providing the connection device. In some examples, block 5100 can be carried out in accordance with method 4000, as illustrated in FIG. 4.

Block 5200 of method 5000 comprises measuring a first power consumption from a first electrical outlet of the connection device. In some embodiments, the first electrical outlet can be similar to an electrical outlet of electrical outlet set 110, such as one of electrical outlets 111 or 112 (FIGS. 1-3). In the same or a different embodiment, the first power consumption can be similar to that described for power consumption 1111 or 1121 (FIGS. 1-3). The first power consumption can be measured as a value in some embodiments, where the value is measured via a first power consumption meter, such as power consumption meter 140 (FIGS. 1-3) or 240 (FIG. 2), coupled to the first electrical outlet. Once measured, the value can be used to generate information about the first power consumption. In some examples, the information about the first power consumption can be generated by the first power consumption meter.

Block 5300 of method 5000 comprises transmitting information about the first power consumption via a power adapter of the connection device. In some embodiments, the information about the first power consumption can be similar to that described for power consumption information 141 (FIGS. 1-3), and can be similar or based on the information about the first power consumption described in block 5200. In the same or different embodiments, the power adapter can be similar to power adapter 130 (FIGS. 1-3).

In some embodiments, block 5300 can comprise forwarding the information about the first power consumption to a network interface of the connection device, where the network interface can be similar to network interface 150 (FIGS. 1-3) in the same or different embodiments. Once received by the network interface, the information about the first power consumption can be transmitted via the power adapter coupled to the network interface. In some embodiments, the power adapter can couple to the network interface through one or more elements. For example, as seen in FIGS. 1 and 3, power adapter 130 couples to network element 150 via surge suppressor 160 and power cord 132.

In the same or a different example, the information about the first power consumption can be transmitted through a power network coupled to the power adapter of the connection device. In the example of FIG. 3, the power network can correspond to power network 310, where power adapter 130 of connection device 100 couples to electrical wiring 311 via power outlet set 312.

In some examples, method 5000 can also comprise block 5400, comprising measuring a second power consumption from a second electrical outlet of the connection device and transmitting information about the second power consumption via the power adapter of the connection device. Block 5400 can be similar to the combination of blocks 5200 and 5300, but applied relative to the second electrical outlet instead of the first electrical outlet of blocks 5200 and 5300. For example, if the first electrical outlet in blocks 5200 and 5300 corresponded to electrical outlet 111 (FIGS. 1-3), then the second electrical outlet of block 5400 could correspond to electrical outlet 112 (FIGS. 1-3).

In some examples, the second power consumption can correspond to power consumption 1121 (FIGS. 1-3), where a value for the second power consumption can be measured via the first power consumption meter coupled to the second electrical outlet in some embodiments, or via a second power consumption meter coupled to the second electrical outlet in other embodiments. In embodiments of the latter type, the second power consumption meter can be similar to power consumption meter 240 (FIG. 2) in some examples.

Once measured, the value for the second power consumption can be used to generate information about the second power consumption, where the information about the second power consumption can form part of power consumption information 141 (FIGS. 1-3) in some embodiments, or of power consumption information 241 (FIG. 2) in other embodiments. In some examples, the information about the second power consumption can be generated by the first power consumption meter. In other examples, the information about the second power consumption can be generated by the second power consumption meter.

Regardless of where generated, the information about the second power consumption can be forwarded to the network interface of the connection device. Once received by the network interface, the information about the second power consumption can be transmitted via the power adapter coupled to the network interface, as described above with respect to the information about the first power consumption in block 5300.

Block 5500 of method 5000 comprises displaying power consumption information at a display of a power monitoring module coupled to the network interface of the connection device. In some examples, the power consumption information can be similar to or based on the information about the first power consumption of block 5300 and/or the information about the second power consumption of block 5400. In the same or a different example, the power consumption information can comprise information about a current drain, a power status, and/or a voltage level corresponding to an electrical outlet of the connection device.

In some embodiments the power monitoring module of block 5500 can be similar to one of the power monitoring modules 322 illustrated in FIG. 3. In such embodiments, the display can be similar to one of the displays 324 also illustrated in FIG. 3. There can also be embodiments where the power monitoring module can comprise one of power consumption meters 140 (FIGS. 1-3), and/or 240 (FIG. 2), and where the display can be similar to display 142 (FIGS. 1-3).

In some examples, as described above with respect to FIG. 3, the power monitoring module can couple to the network interface via at least one of the first electrical outlet, the second electrical outlet, a power network, a power grid, a powerline network, the power adapter, a power plug, a network adapter, a powerline adapter, an Ethernet connection, an optical interface, a USB connection, a wireless connection, a modem, a router, and/or the Internet.

Method 5000 can also comprise block 5600 in some examples, comprising controlling a first power output of the first electrical outlet via the network interface of the connection device. In some examples, the first power output can be controlled as described above with respect to power output 3112 of electrical outlet 111. In some examples, a second power output of the second electrical outlet can also be controlled in a similar fashion.

Block 5700 comprises communicating a first networking device and a second networking device via the network interface of the connection device, and can be part of method 5000 in some examples. In some examples, such as illustrated in FIG. 3, the first and second networking devices of block 5700 can each comprise one of electrical devices 320, 330, 340, 350, or 360, modems 370, and/or routers 375, among others. In the same or other examples, the first and second networking devices couple to the network interface via a communications port set that can comprise, for example, at least one of the first electrical outlet, the second electrical outlet, the power adapter, an Ethernet port, a USB port, an optical interface port, and/or a wireless port. In the same or different examples, the communications port set can be similar to communications port set 180 (FIGS. 1-3). In embodiments where method 5000 comprises block 5700, when communicating the first and second networking devices, the connection device of method 5000 can function as a network, switch, and/or router in some situations.

In some examples, one or more of the different blocks of method 4000 or method 5000 can be combined into a single step or performed simultaneously, and/or the sequence of such blocks can be changed. For example, blocks 4130 and 4140 in method 4000 could be combined into a single block, for example, in situations where the power consumption meter and the network interface comprise parts of one module within the body of the connection device. As another example, the measuring of the first power consumption in block 5200 can be performed simultaneously with the measuring of the second power consumption in block 5400 of method 5000. In some examples, the blocks of method 4000 or method 5000 can be subdivided into several sub-blocks. For example, block 5400 in method 5000 can be subdivided into a sub-block for measuring the second power consumption and a sub-block for transmitting information about the second power consumption. There can also be examples, where method 4000 or method 5000 can comprise further or different steps. As an example, steps related to the provision or operation of additional electrical outlets for the connection devices of methods 4000 and/or 5000 may be added in accordance with the present disclosure.

Although the power management connection devices and related methods herein have been described with reference to specific embodiments, various changes may be made without departing from the spirit or scope of the disclosure. For example, even though connection devices 100 (FIGS. 1, 3) and 200 (FIG. 2) have been presented as comprising only two electrical outlets, there can be embodiments similarly configured to comprise and support further electrical outlets similar to or different from electrical outlets 111 and/or 112. Additional examples of such changes have been given in the foregoing description. Accordingly, the disclosure of embodiments is intended to be illustrative of the scope of the invention and is not intended to be limiting. It is intended that the scope of this application shall be limited only to the extent required by the appended claims. The power management connection devices and related methods discussed herein may be implemented in a variety of embodiments, and the foregoing discussion of certain of these embodiments does not necessarily represent a complete description of all possible embodiments. Rather, the detailed description of the drawings, and the drawings themselves, disclose at least one preferred embodiment, and may disclose alternative embodiments.

All elements claimed in any particular claim are essential to the embodiment claimed in that particular claim. Consequently, replacement of one or more claimed elements constitutes reconstruction and not repair. Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A power management system comprising:
a connection device comprising:
an electrical outlet set with at least a first electrical outlet;
a first power consumption meter coupled to the first electrical outlet;
a network interface coupled to the first power consumption meter; and
a power adapter coupled to the network interface;
wherein:
the first power consumption meter is configured to measure a first power consumption of the first electrical outlet; and
the network interface is configured to transmit information about the first power consumption via the power adapter.

2. The system of claim 1, wherein:
the electrical outlet set further comprises a second electrical outlet;
the second electrical outlet is coupled to the first power consumption meter;
the first power consumption meter is configured to measure a second power consumption of the second electrical outlet; and
the network interface is configured to transmit information about the second power consumption via the power adapter.

3. The system of claim 1, wherein:
the connection device further comprises a second power consumption meter coupled to the network interface;
the electrical outlet set further comprises a second electrical outlet coupled to the second power consumption meter;
the second power consumption meter is configured to measure a second power consumption of the second electrical outlet; and
the network interface is configured to transmit information about the second power consumption via the power adapter.

4. The system of claim 1, further comprising:
a power network coupled to the power adapter of the connection device;
wherein the information about the first power consumption is transmitted through the power network.

5. The system of claim 1, further comprising:
a power monitoring module coupled to the network interface; and
a display coupled to the power monitoring module;
wherein the power monitoring module is configured to:
receive the information about the first power consumption from the network interface; and
display the information about the first power consumption on the display.

6. The system of claim 5, wherein:
the power monitoring module is coupled to the network interface of the connection device via at least one of:
the first electrical outlet;
the power network;
a power grid;
a powerline network;
the power adapter;
a power plug;
a network adapter;
a powerline adapter;
an Ethernet connection;
an optical interface;
a USB connection;
a wireless connection;
a modem;
a router; or
the Internet.

7. The system of claim 5, wherein:
the power monitoring module is configured to process the information about the first power consumption to display at least one of:
a current drain;
a power status; or
a voltage level.

8. The system of claim 5, wherein:
the display presents the information about the first power consumption via a graphical user interface.

9. The system of claim 5, wherein:
the power monitoring module is configured to control a first power output of the first electrical outlet via the network interface of the connection device.

10. The system of claim 9, wherein:
the network interface is configured to control the first power output via the first power consumption meter.

11. The system of claim 9, wherein:
the power monitoring module is configured to automatically control the first power output of the first electrical outlet at the connection device based on the information about the first power consumption.

12. The system of claim 9, wherein:
the power monitoring module is configured to accept and process a control input to control the first power output of the first electrical outlet at the connection device.

13. The system of claim 12, wherein:
the control input is entered via a graphical user interface on the display.

14. The system of claim 1, wherein:
the connection device further comprises:
a communications port set comprising at least one of:
the first electrical outlet;
a second electrical outlet;
the power adapter;
an Ethernet port;
a USB port;
an optical interface port; or
wireless port.

15. The system of claim 14, further comprising:
a first networking device coupled to a first port of the communications port set; and
a second networking device coupled to a second port of the communications port set;
wherein the first networking device and the second networking device communicate with each other via the network interface of the connection device.

16. The system of claim 1, wherein:
the network interface of the connection device transmits the information via the power adapter using at least one of:
a frequency shift keying mechanism; or
an orthogonal frequency-division multiplexing mechanism.

17. The system of claim 1, wherein:
the network interface of the connection device is compliant with at least one of:
a HomePlug Alliance standard;
a CEPCA standard; or
a UPA standard.

18. The system of claim 1, wherein:
the connection device further comprises a surge protection module coupled to the power adapter.

19. A method comprising:
measuring a first power consumption from a first electrical outlet of a connection device; and
transmitting information about the first power consumption via a power adapter of the connection device.

20. The method of claim 19, further comprising:
controlling a first power output of the first electrical outlet via a network interface of the connection device.

21. The method of claim 19, wherein:
measuring the first power consumption from the first electrical outlet comprises:
measuring a value of the first power consumption via a first power consumption meter coupled to the first electrical outlet; and
generating the information about the first power consumption based on the value measured by the first power consumption meter;
and
transmitting the information about the first power consumption comprises:
forwarding the information about the first power consumption to a network interface of the connection device; and
transmitting the information about the first power consumption via the power adapter coupled to the network interface.

22. The method of claim 19, further comprising:
measuring a second power consumption from a second electrical outlet of the connection device; and
transmitting information about the second power consumption via the power adapter of the connection device;
wherein:
measuring the second power consumption from the second electrical outlet comprises:
measuring a second value of the second power consumption via at least one of:
the first power consumption meter coupled to the second electrical outlet; or
a second power consumption meter coupled to the second electrical outlet;
and
generating the information about the second power consumption based on the second value;
and
transmitting the information about the second power consumption comprises:
forwarding the information about the second power consumption to the network interface of the connection device; and
transmitting the information about the second power consumption via the power adapter coupled to the network interface.

23. The method of claim 19, further comprising:
facilitating communication between a first networking device and a second networking device via a network interface of the connection device;
wherein the first and second networking devices couple to the network interface via a communications port set comprising at least one of: the first electrical outlet, the power adapter, an Ethernet port, a USB port, an optical interface port, or a wireless port.

24. The method of claim 19, wherein:
transmitting the information comprises:
transmitting the information through a power network coupled to the power adapter of the connection device.

25. The method of claim 19, further comprising:
displaying the information at a display of a power monitoring module coupled to a network interface of the connection device;
wherein:
the power monitoring module couples to the network interface of the connection device via at least one of the first electrical outlet, a power network, a power grid, a powerline network, the power adapter, a power plug, a network adapter, a powerline adapter, an Ethernet connection, an optical interface, a USB connection, a wireless connection, a modem, a router, or the Internet; and
the power monitoring module processes the information to display at least one of a current drain, a power status, or a voltage level.

26. A method comprising:
providing a body of a connection device;
providing an electrical outlet set coupled to the body and comprising a first electrical outlet;
providing a first power consumption meter coupled to the first electrical outlet and configured to measure a first power consumption of the first electrical outlet;
providing a network interface coupled to the first power consumption meter and configured to transmit information about the first power consumption via a power adapter;
providing the power adapter coupled to the network interface and to the body of the connection device; and
providing a communications port set coupled to the network interface and comprising at least one of: the electrical outlet set, the power adapter, an Ethernet port, a USB port, an optical interface port, or a wireless port.

27. The method of claim 26, further comprising:
providing a display coupled to the first power consumption meter to display the information about the first power consumption.

28. The method of claim 26, wherein:
providing the network interface comprises:
providing the network interface to control a first power output of the first electrical outlet via the first power consumption meter.
